(19) United States
(12) Patent Application Publication
(10) Pub. No.: US 2014/0147985 A1
(43) Pub. Date: May 29, 2014

(54) METHODS FOR THE FABRICATION OF SEMICONDUCTOR DEVICES INCLUDING SUB-ISOLATION BURIED LAYERS

(71) Applicant: FREESCALE SEMICONDUCTOR, INC., Austin, TX (US)

(72) Inventors: Jay P John, Chandler, AZ (US); Scott A Hildreth, Austin, TX (US); James A Kirchgessner, Tempe, AZ (US)

(73) Assignee: FREESCALE SEMICONDUCTOR, INC., Austin, TX (US)

(21) Appl. No.: 13/689,274

(22) Filed: Nov. 29, 2012

(51) Int. Cl. H01L 21/762; H01L 21/76; H01L 21/265

(52) U.S. Cl. CPC H01L 21/76224; H01L 21/265; H01L 21/76
USPC 438/424; 438/524; 438/400

(57) ABSTRACT

Methods for fabricating a semiconductor device are provided. In one embodiment, the method includes forming a Sub-Isolation Buried Layer (SIBL) stack over a semiconductor substrate. The SIBL stack includes a polish stop layer and a sacrificial implant block layer. The SIBL stack is patterned to create an opening therein, and the semiconductor substrate is etched through the opening to produce a trench in the semiconductor substrate. Ions are implanted into the semiconductor substrate at a predetermined energy level at which ion penetration through the patterned SIBL stack is substantially prevented to create a SIBL region beneath the trench. After ion implantation, a trench fill material is deposited over the SIBL stack and into the trench. The semiconductor device is polished to remove a portion of the trench fill material along with the sacrificial implant block layer and expose the polish stop layer.

### TECHNICAL FIELD

Embodiments of the present invention relate generally to semiconductor fabrication techniques and, more particularly, to methods for fabricating heterojunction bipolar transistors and other semiconductor devices including sub-isolation buried layers.

### BACKGROUND

Heterojunction bipolar transistors (“HBTs”) are capable of operating at frequencies exceeding those at which other conventionally-known transistors operate, including bipolar junction transistors having emitter and base regions formed from a single semiconductor material. HBTs are thus well-suited for usage in radio-frequency applications and other platforms requiring high frequency signal processing and power efficiency, such as automotive radar products. The performance of HBTs can, however, be undesirably limited by high parasitic extrinsic collector resistances (“R_{cx}”). To reduce the lateral component of R, for a given device, heavily-doped, low resistance buried regions or layers can be formed in the HBT semiconductor region between the collector and emitter regions. Such low resistance buried layers may be formed below dielectric-filled trenches and referred to as “Sub-Isolation Buried Layers” or, more simply, “SIBL regions.” In one approach, the SIBL regions are formed by first etching shallow trenches in the semiconductor substrate and, specifically, into an epitaxial silicon layer grown over a base substrate. An SIBL implant is then performed during which the substrate is bombarded with ions to create the SIBL regions beneath the shallow trenches. The trenches are filled with a dielectric material, such as a flowable oxide, to produce an electrical isolation structure above the SIBL regions. Additional processing steps are then performed to complete fabrication of the HBT. Further description of this fabrication technique is provided in U.S. Pat. No. 7,084,485 B2, issued Aug. 1, 2006, and assigned to the assignee of the instant Application, the contents of which are hereby incorporated by reference.

### BRIEF DESCRIPTION OF THE DRAWINGS

At least one example of the present invention will hereinafter be described in conjunction with the following figures, wherein like numerals denote like elements, and:

FIG. 1 is a cross-sectional view of a heterojunction bipolar transistor including two Sub-Isolation Buried Layers and produced in accordance with an exemplary embodiment of the semiconductor fabrication method described herein;

FIG. 2 is a cross-sectional view of a portion of the heterojunction bipolar transistor shown in FIG. 1 in a partially-completed state and illustrating the undesired doping of the device active areas that can occur during the Sub-Isolation Buried Layer implant when a hardmask stack is utilized having a relatively thin polish stop layer and/or lacking a sacrificial implant block layer;

FIGS. 3-13 are cross-sectional views of a semiconductor device including a heterojunction bipolar transistor (partially shown), illustrated at various stages of manufacture, and produced in accordance with an exemplary embodiment of the semiconductor fabrication method; and

FIGS. 14 and 15 are cross-sectional views of a voltage-variable capacitor in partially-completed and completed states, respectively, and produced in accordance with a further exemplary embodiment of the semiconductor fabrication method.

For simplicity and clarity of illustration, the drawing figures illustrate the general manner of construction and may omit depiction, descriptions, and details of well-known features and techniques to avoid unnecessarily obscuring the exemplary and non-limiting embodiments of the invention described in the subsequent Detailed Description. It should further be understood that features or elements appearing in the accompanying figures are not necessarily drawn to scale unless otherwise stated. For example, the dimensions of certain elements or regions in the figures may be exaggerated relative to other elements or regions to improve understanding of embodiments of the invention.

### DETAILED DESCRIPTION

The following Detailed Description is merely exemplary in nature and is not intended to limit the invention or the application and uses of the invention. Any implementation described herein as exemplary is not necessarily to be construed as preferred or advantageous over other implementations. Furthermore, there is no intention to be bound by any theory presented in the preceding Background or the following Detailed Description.

Terms such as “first,” “second,” “third,” “fourth,” and the like, if appearing in the description and the subsequent claims, may be utilized to distinguish between similar elements and are not necessarily used to indicate a particular sequential or chronological order. Such terms may thus be used interchangeably and that embodiments of the invention are capable of operation in sequences other than those illustrated or otherwise described herein. Furthermore, terms such as “comprise,” “include,” “have,” and the like are intended to cover non-exclusive inclusions, such that a process, method, article, or apparatus that comprises a list of elements is not necessarily limited to those elements, but may include other elements not expressly listed or inherent to such process, method, article, or apparatus. The term “coupled,” as appearing herein, is defined as directly or indirectly connected in an electrical or non-electrical manner. Furthermore, the terms “substantial” and “substantially” are utilized to indicate that a particular feature or condition is sufficient to accomplish a stated purpose in a practical manner and that minor imperfections or variations, if any, are not significant for the stated purpose. Finally, as appearing herein, the term “over,” the term “overlying,” the term “under,” and similar terms are phrases are utilized to indicate relative positioning between two structural elements or layers and not necessarily to denote physical contact between structural elements.

As used herein, the term “semiconductor” is intended to include any semiconductor material, whether single crystal, poly-crystalline or amorphous. Such materials include type IV semiconductors, non-type IV semiconductors, and compound semiconductors, as well as organic and inorganic semiconductors. Further, the term “substrate,” the phrase “semiconductor substrate,” and similar terms and phrases are utilized to denote single crystal structures, polycrystalline structures, amorphous structures, thin film structures, and layered structures, such as semiconductor-on-insulator (SOI) structures, insulator on semiconductor (IOS) structures, base structures over which one or more additional layers have been epitaxially grown, and combinations thereof. For convenience of explanation and not intended to be limiting, various device types and/or doped semiconductor regions may be identified as being of N type or P type, but this is merely for convenience of description and not intended to be limiting, and such identification may be replaced by the more general description of being of a “first conductivity type” or a “second, opposite conductivity type” wherein the first type may be either N or P type and the second type is then either P or N type.

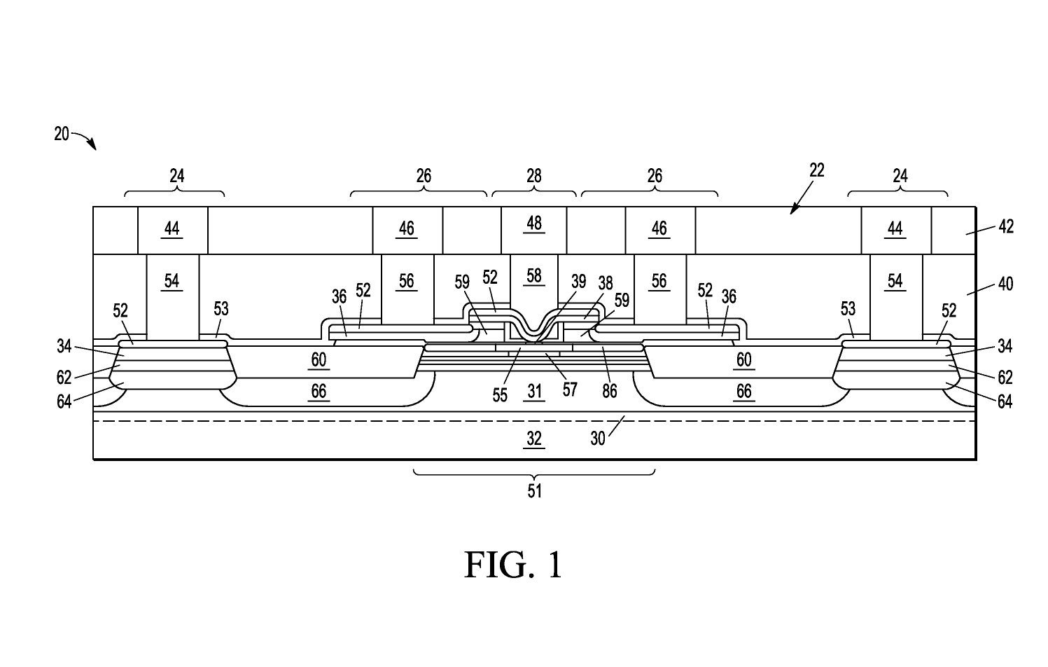

FIG. 1 is a cross-sectional view of a portion of a semiconductor device 20 produced in accordance with an exemplary embodiment of the semiconductor fabrication method. In this particular example, the illustrated portion semiconductor device 20 includes a bipolar transistor 22 and, specifically, a Heterojunction Bipolar Transistor or “HBT.” While the illustrated portion of device 20 is shown as including only a single transistor in FIG. 1 for ease of explanation, it will be understood that semiconductor device 20 can include any number of additional active and/or passive components formed on a common semiconductor substrate, and that such components may be electrically interconnected to produce one or more integrated circuits. In certain implementations, semiconductor device 20 may assume the form of a Bipolar and Complementary Metal-Oxide Semiconductor (“BiCMOS”) device including one or more pairs of Complimentary Metal-Oxide Semiconductor (“CMOS”) transistors, which are fabricated in conjunction with HBT 22 utilizing conventionally-known processing steps.

With continued reference to FIG. 1, HBT 22 includes collector conductive connections 24, base conductive connections 26, and emitter conductive connection 28. Collector conductive connections 24, base conductive connections 26, and emitter conductive connection 28 are formed over a semiconductor region of semiconductor substrate 32. Semiconductor substrate 32 can be a bulk silicon wafer or any other substrate on which HBT 22, and any additional transistors or other components included within semiconductor device 20, can be fabricated including, but not limited to, other type IV semiconductor materials, as well as type III-V and II-VI semiconductor materials, organic semiconductors, and combinations thereof, whether in bulk single crystal, polycrystalline form, thin film form, semiconductor-on-insulator form, or combinations thereof. An epitaxially-grown semiconductor layer 30, such as a layer of epitaxially-grown silicon (“eSi”), may be grown over the base substrate and form an upper portion of semiconductor substrate 32. Semiconductor substrate 32 has a first conductivity type; base electrodes 36, base layer 55, and extrinsic base layers 59 are also of the first conductivity type. Emitter electrode 38 and emitter diffusion 39 have a second, opposing conductivity type. The collector region is comprised of a number of doped semiconductor regions formed in eSi layer 30, also of the second opposing conductivity type. The collector region includes collector electrodes 34, resistor-implanted regions 64, collector well regions 62 and 31, Sub-Isolation Buried Layers 66 (also referred to herein as “SIBL regions 66”), and a selectively-implanted collector region 57. In some embodiments, all of these collector regions are not included; however, collector electrode 34, SIBL region 66, and collector well region 31 will typically be included within a given HBT. In one embodiment, semiconductor substrate 32 is a P-type substrate over which a P-type eSi layer 30 has been grown; while the collector regions 34, 64, 62, 31, 66, and 57 and the emitter regions 38 and 39 are N-type regions.

Collector conductive connections 24 include collector metal layers 44 and collector contacts 54. Base conductive connections 26 include base metal layers 46 and base contacts 56. Emitter conductive connection 28 includes emitter metal layer 48 and emitter contact 58, which may be formed using different electrically-conductive metals; e.g., layers 44, 46, and 48 may be copper or aluminum, while contacts 54, 56, and 58 may be tungsten plugs. Collector electrodes 34, base electrodes 36, and emitter electrode 38 are overlaid by a first dielectric or isolation layer 40, which is, in turn, overlaid by a second dielectric layer 42. Collector conductive connections 24, base conductive connections 26, and emitter conductive connection 28 are formed within dielectric layers 42 and 40. Conductive connections 24, 26, and 28 are electrically coupled to their corresponding electrodes 34, 36, and 38 (i.e., collector metal layers 44 are electrically coupled to collector contacts 54, and collector electrodes 34; base metal layers 46 are electrically coupled to base contacts 56 and base electrodes 36; and emitter metal layer 48 is electrically coupled to emitter contact 58 and emitter electrode 38). To decrease resistance at the contact-plug junctures, a silicide layer 52 may be formed over each of the electrode regions 34, 36, and 38 under the contacts 54, 56, 58. A passivation or capping layer 53 may be formed between the upper surface of semiconductor substrate 32 and dielectric layer 40, as further shown in FIG. 1.

Base electrode 36, extrinsic base layers 59, and base layer 55 are formed over active area 51 of HBT 22. In one embodiment wherein HBT 22 is a SiGe device, epitaxially-grown base layer 55 includes an undoped silicon layer epitaxially grown over the upper surface of substrate 32, a silicon-germanium layer epitaxially grown over the undoped silicon layer, and a doped silicon layer epitaxially grown over the silicon-germanium layer. Emitter electrode 38 and emitter diffusion 39 are formed over base electrode 36 and base layer 55. In the exemplary embodiment shown in FIG. 1, a selectively-implanted collector region 57 is formed beneath the undoped silicon layer in epitaxially-grown layer 55. Extrinsic base layers 59 are advantageously formed between epitaxially-grown layer 55 and base electrodes 36 to reduce the resistance therebetween. Dielectric-filled trenches 60 are provided underneath base electrodes 36 and adjacent collector electrodes 34, underlying collector well regions 62, and underlying resistor-implanted regions 64. As will be described in detail below, SIBL regions 66 are further formed underneath trenches 60. Notably, SIBL regions 66 are formed to have the same conductivity type as collector and emitter regions (and, therefore, opposite that of semiconductor substrate 32 and the base regions). All of the collector semiconductor regions 34, 62, 64, 66, 31, and 57 may be electrically coupled and doped with the same second conductivity type. SIBL region 66 has a significantly higher doping concentration than adjacent collector regions 62, 64, 31, and 57. The inclusion of SIBL regions 66 thus provides a lower resistance path between collector conductive connections 24 and HBT active area 51. By providing such a low resistance path between collector conductive connections 24 and HBT active area 51, SIBL regions 66 decrease the lateral component of the parasitic extrinsic collector resistance of HBT 22 and improve device performance. Further description of semiconductor devices including Sub-Isolation Buried

Layers similar to those shown in FIG. 1 is provided in U.S. Pat. No. 7,084,485 B2, as referenced in the foregoing section entitled “BACKGROUND.”

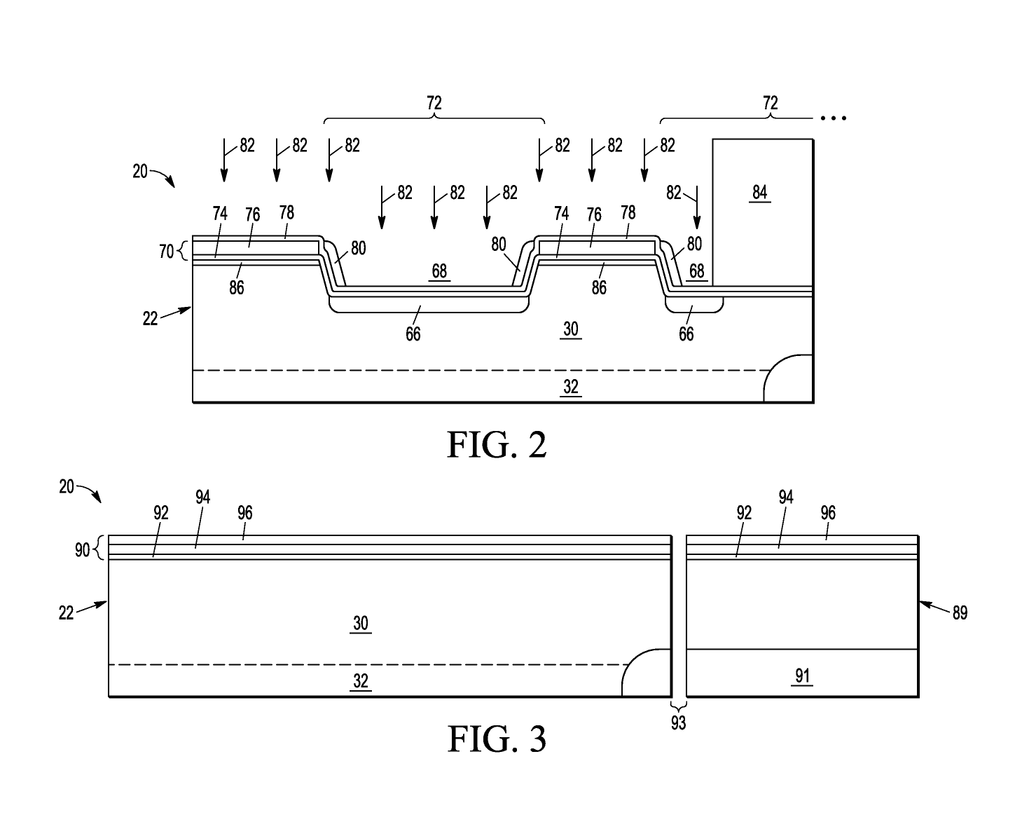

During fabrication of HBT 22, an SIBL implant is utilized to create SIBL regions 66 beneath shallow trenches previously etched into semiconductor substrate 32. An example of this process step is illustrated in FIG. 2 wherein semiconductor device 20, and specifically HBT 22, is shown in a partially-fabricated state after shallow trenches 68 have been created in eSi layer 30 of substrate 32. At this juncture in the fabrication process, an active or hardmask stack 70 (referred to herein as “SIBL stack 70”) has been formed over the upper surface of substrate 32 and patterned to include openings 72 through which shallow trenches 68 are formed during the trench etching process (described below). In the exemplary embodiment shown in FIG. 2, SIBL stack 70 includes a base layer 74 formed over the upper surface of semiconductor substrate 32, and a polish stop layer 76 formed over the upper surface of base layer 74. Polish stop layer 76 can be formed from an active nitride and, in such cases, may also be referred to as the “active nitride layer.” An additional oxide layer 78 has been deposited over patterned SIBL stack 70 and into trench 68; and SIBL spacers 80 have been formed over the sidewalls of trenches 68 by deposition of a suitable spacer-forming material, such as a nitride, and blanket etching. As generically represented in FIG. 2 by arrows 82, during the SIBL implant, semiconductor device 20 is bombarded with a selected ion species to create sub-isolation SIBL regions 66 underlying trenches 68; e.g., if N-type SIBL regions 66 are to be formed, semiconductor device 20 may be bombarded with arsenic or phosphorus ions. SIBL stack 70 serves as an implant mask during the SIBL implant such that SIBL regions 66 self-align to openings 72 provided through stack 70 and, therefore, to the sidewalls of shallow trenches 68. As further indicated in FIG. 2, any additional, non-HBT components (e.g., one or more CMOS devices) included within semiconductor device 20 may be covered by a mask layer 84 prior to the SIBL implant. After formation of sub-isolation SIBL regions 66, additional processing steps are then performed to complete the fabrication of semiconductor device 20; e.g., an oxide layer may be blanket deposited over device 20 and into shallow trenches 68, the overburden of the deposited oxide may then be removed utilizing a Chemical Mechanical Planarizing or Polishing (“CMP”) process to yield dielectric-filled trenches 60 (FIG. 1), the remaining portions of the SIBL stack 70 may be stripped, and additional processing steps performed to complete the fabrication of semiconductor device 20.

During the above-described CMP process, partially-completed semiconductor device 20 may be polished or planarized in the presence of a slurry that preferentially removes the trench fill material (e.g., an oxide) over the material from which polish stop layer 76 is formed (e.g., an active nitride) during the CMP process. Advancements in CMOS processing technology have lead to the development of so-called “highly selective slurries,” which support relatively rapid removal of the target material(s) during the CMP process, while disparate materials are removed at a significantly lower rate. When such a highly selective slurry is utilized to remove the overburden resulting from the shallow trench fill process, relatively little material is removed from polish stop layer 76 included within SIBL stack 70. This, in turn, allows polish stop layer 76 to be deposited to have a reduced thickness; e.g., a thickness less than 2000 angstroms and, in certain cases, a thickness of about 950 angstroms. While this provides certain advantages, it has been discovered that imparting polish stop layer 76 with such a reduced thickness can diminish the ability of the SIBL stack 70 to block penetration of ions during the SIBL implant. Consequently, and as further illustrated in FIG. 2, undesired doping of the active areas of semiconductor device 20 may occur during the SIBL implant resulting in the formation of relatively thin doped layers 86 under patterned stack 70 having a conductivity opposite substrate 32; e.g., in embodiments wherein eSi layer 30 of substrate 32 is P-type, thin N-layers 86 may be formed within the device active areas immediately under patterned SIBL stack 70. Inadvertently-doped layers 86 can negatively affect the capacitance, base resistance, and other performance characteristics of HBT 22.

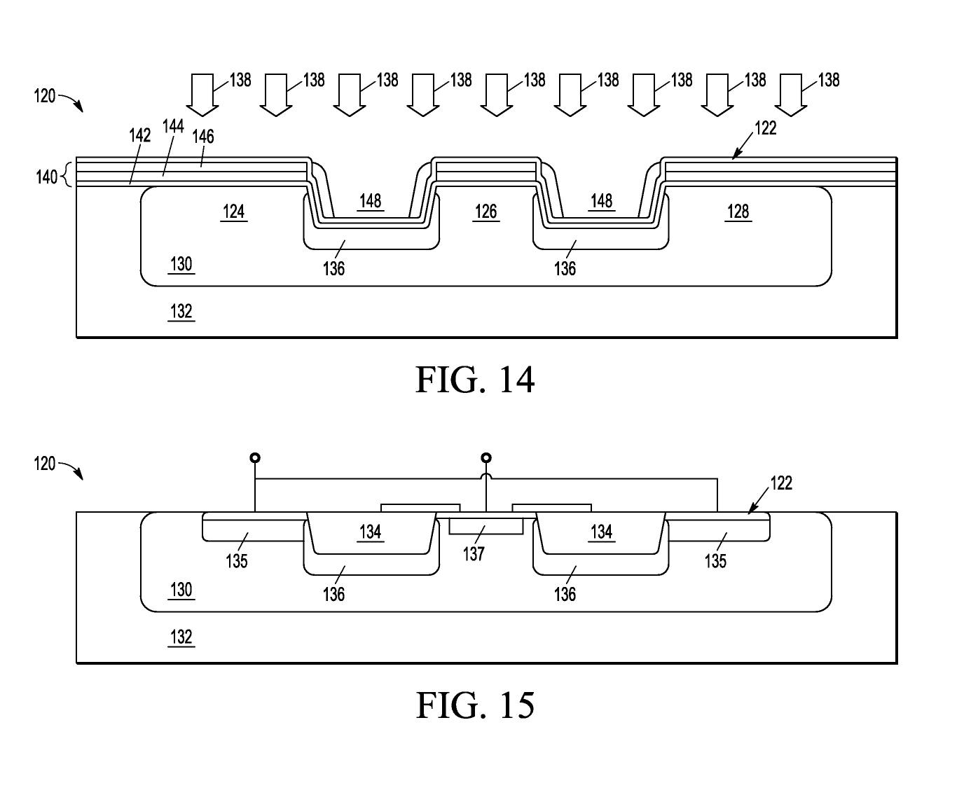

The following describes exemplary embodiments of a method for producing a semiconductor device wherein undesired doping of the device active areas during the SIBL implant is minimized or avoided entirely. To provide a convenient, albeit non-limiting illustration, the following will describe an exemplary embodiment of the fabrication method in conjunction with the fabrication of semiconductor device 20, as illustrated in FIGS. 3-13 at various stages of manufacture. It will be appreciated, however, that embodiments of the below-described fabrication method can be utilized to produce various other types of semiconductor devices containing Sub-Isolation Buried Layers including, but not limited to, voltage-variable capacitors, such as the voltage-variable capacitor described below in conjunction with FIGS. 14 and 15. The fabrication steps illustrated in FIGS. 3-13 and described below are provided by way of example only; alternative embodiments of the fabrication method may include additional steps, omit certain steps, substitute or alter certain steps, or perform certain steps in an order different than that illustrated in the accompanying figures. Various steps in the manufacture of bipolar heterojunction transistors are well-known and, in the interests of brevity, will only be mentioned briefly herein or will be omitted entirely without providing the well-known process details.

In embodiments of the below-described semiconductor fabrication method, the SIBL stack is formed to include at least one additional layer referred to herein as a “sacrificial implant block layer.” The sacrificial implant block layer enhances the ability of the SIBL stack to block ion penetration during the SIBL implant and, thus, prevents or at least decreases undesired doping of the device active areas during fabrication of the semiconductor device. Embodiments of the below-described fabrication method are advantageously employed under any conditions wherein the SIBL stack, absent the below-described sacrificial implant block layer, is insufficient to prevent the undesired doping of the active device regions during the SIBL implant, whether due to the inclusion of a relatively thin polish stop layer in the SIBL stack, as previously described, and/or due to the performance of a high energy SIBL implant capable of penetrating the polish stop layer (and any other layers included within the SIBL stack) even when formed to be relatively thick; e.g., to have a thickness exceeding about 2000 angstroms.

In keeping with the exemplary embodiment described above in conjunction with FIG. 1, FIGS. 3-13 illustrate semiconductor device 20, and specifically HBT 22, as fabricated on a semiconductor substrate 32 including a base layer over which an eSi layer 30 has been grown. As previously described, semiconductor device 20 may be fabricated to include one or more additional components in addition to HBT 22. To further emphasize this point, semiconductor device 20 is illustrated in FIGS. 3-13 as further including an additional transistor 89 formed on semiconductor substrate 32 (only a small portion of transistor 89 is illustrated). In embodiments wherein semiconductor device 20 assumes the form of a SiGe BiCMOS device, transistor 89 may be an NMOS transistor included within the BiCMOS device and formed over a buried layer 91. In this case, and by way of example, buried layer 91 may be a P+ buried layer and substrate 32 may be a P− substrate. As indicated in FIGS. 3-13 by lateral gap 93, transistor 89 need not be formed immediately adjacent HBT 22.

With reference to FIG. 3, a hardmask or SIBL stack 90 is deposited over upper surface of semiconductor substrate 32 and, specifically, over the upper surface of eSi layer 30. In the illustrated example, SIBL stack 90 is formed to include three layers: (i) a base layer 92, (ii) a polish stop layer 94 formed over base layer 92, and (iii) a sacrificial implant block layer 96 formed over polish stop layer 94. Base layer 92 is conveniently formed from a pad oxide, which may be grown over and into an upper portion of substrate 32. Base layer 92 may be grown to thickness of, for example, about 145 angstroms. By comparison, polish stop layer 94 can be formed via the blanket deposition of a chosen material onto base layer 92. In an embodiment, polish stop layer 94 is advantageously formed from a material having a relatively low removal rate during the below-described CMP process as compared to the material from which block layer 96 is formed and as compared to the material utilized to fill the shallow trenches, as described more fully below. In one embodiment, polish stop layer 94 is an active nitride layer deposited to thickness between about 300 and about 2000 angstroms, and, more preferably, to a thickness between about 500 and about 1500 angstroms.

As briefly described above and as discussed more fully below, sacrificial implant block layer 96 is formed over polish stop layer 94 to supplement or enhance the implant blocking ability of SIBL stack 90. In this regard, sacrificial implant block layer 96 can be formed from any material providing the desired implant blocking properties, while also be readily removable during the below-described CMP process. In one group of embodiments, sacrificial implant block layer 96 is formed from an oxide. More specifically, implant block layer 96 may comprise silicon oxide deposited over semiconductor substrate 32 utilizing a chemical vapor deposition (CVD) technique, such as low temperature Plasma-Enhanced CVD or Low Pressure CVD performed utilizing silane (SiH₄) or tetraethylorthosilicate (Si(OC₂H₅)₄ or “TEOS”) chemistries. In another embodiment, implant block layer 96 is formed via the deposition of a high density plasma oxide. In still further implementations, implant block layer 96 may be formed from polysilicon. In embodiments wherein sacrificial implant block layer 96 is formed from a material having a lower density, such as a TEOS oxide, a densification process may be performed after deposition of layer 96. In such a case, densification may be accomplished by heat treatment of semiconductor device 20; e.g., a rapid thermal anneal may be performed in furnace over predetermined temperature range (e.g., 700 to 1100° C.) in an oxidizing atmosphere. In other embodiments wherein sacrificial implant block layer 96 is deposited to have a relatively high density, such as when block layer 96 is formed from a high density plasma oxide, such a densification step may be unnecessary.

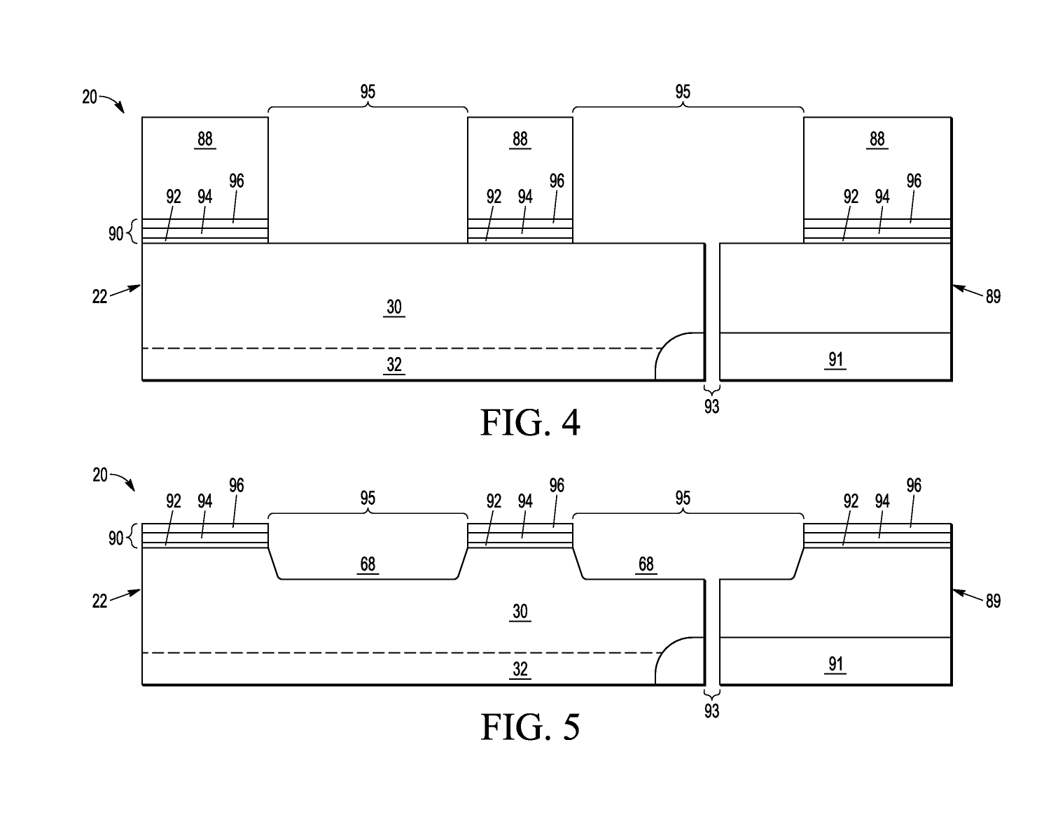

Continuing with the exemplary semiconductor fabrication process, SIBL stack 90 is patterned to create a number of openings 95 therein and yield the structure shown in FIG. 4. SIBL stack 90 can be patterned utilizing a conventional lithographical process wherein a photoresist layer 88 is deposited over SIBL stack 90, exposed to an image pattern, and treated with a developing solution to form openings therein. Photoresist layer 88 may be included within a tri-layer lithographical stack further including, for example, an optical planarization layer (“OPL”) and an anti-reflective coating (“ARC”) layer (not shown). An anisotropic dry etch, such as a reactive ion etch (“RIE”), can then be performed utilizing a chemistry selected to etch each layer of SIBL stack 90 to remove the areas of stack 90 exposed through the patterned photoresist or lithographical stack. By way of non-limiting example, a CF₄/HBr or HBr/Cl₂/HeO₂ chemistry mixture can be employed in etching of sacrificial implant block layer 96 when formed from an oxide or polysilicon, respectively; and a CF₄/HBr mixture can be utilized in the etching of both polish stop layer 94 and base layer 92 when formed from a nitride and oxide, respectively. Various other etch chemistries can be employed to layers 92, 94, and 96, as appropriate, in further implementations.

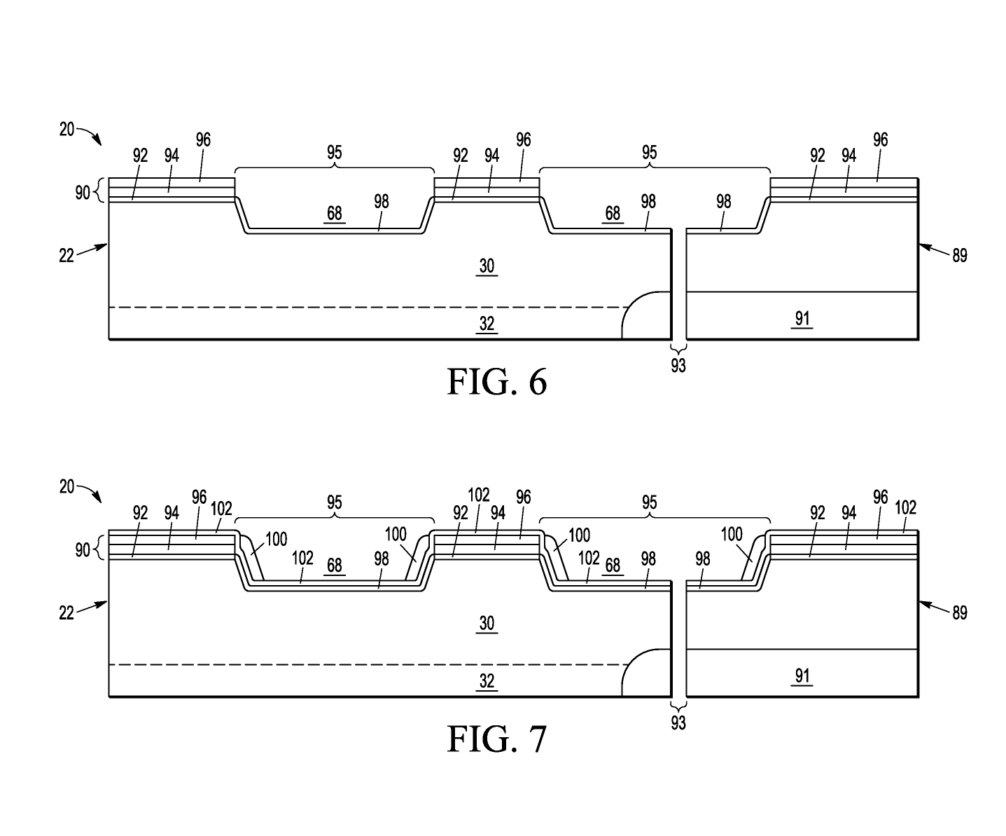

Turning next to FIG. 5, an etching process is performed to remove those portions of semiconductor substrate 32 exposed through openings 95 in SIBL stack 90 and form shallow trenches 68. Etching is carried-out utilizing a chemistry designed to etch the parent material of semiconductor substrate 32 and, specifically, eSi layer 30; e.g., a HBr/Cl₂/HeO₂ chemistry may be utilized when layer 30 is formed from silicon. As generally illustrated in FIG. 5, etching may impart the sidewalls of shallow trenches 68 with a slanted profile, although it will be appreciated that the profile of trench sidewalls and the aspect ratio of trenches 68 will vary depending upon the particular etch employed. Afterwards, any remaining portion of photoresist 88 or the photolithographical stack may be stripped by, for example, ashing. After formation of shallow trenches 68 in semiconductor substrate 32, a trench liner 98 may next be formed along the bottom and sidewall surfaces of trenches 68 (shown in FIG. 6). Trench liner 98 may be produced in various different manners and from various different materials; however, in one embodiment, a relatively thin (e.g., ˜200 angstrom) layer of silicon oxide is grown over the exposed areas of substrate 32 to produce trench liner 98.

It may be desired to form one or more temporary structures in shallow trenches 68 to direct the SIBL implant into desired areas of semiconductor substrate 32, while preventing the undesired doping of surrounding areas of substrate 32. For example, as shown in FIG. 7, sidewall spacers 100 may be formed within shallow trenches 68 by blanket deposition of a suitable spacer-forming material (e.g., silicon nitride or an ultra-low k material) to a desired thickness (e.g., about 700 angstrom) and then blanket etching. Prior to the deposition of the spacer-forming material, a thin oxide layer 102 may be formed over the upper surface of sacrificial implant block layer 96 and trench liner 98. In one embodiment, oxide layer 102 is a TEOS oxide deposited to a thickness of about 300 angstroms. The foregoing example notwithstanding, sidewall spacers 100 need not be employed in all embodiments and may be unnecessary in instances wherein encroachment of the Sub-Isolation Buried Layers into the device active areas is permissible or desired.

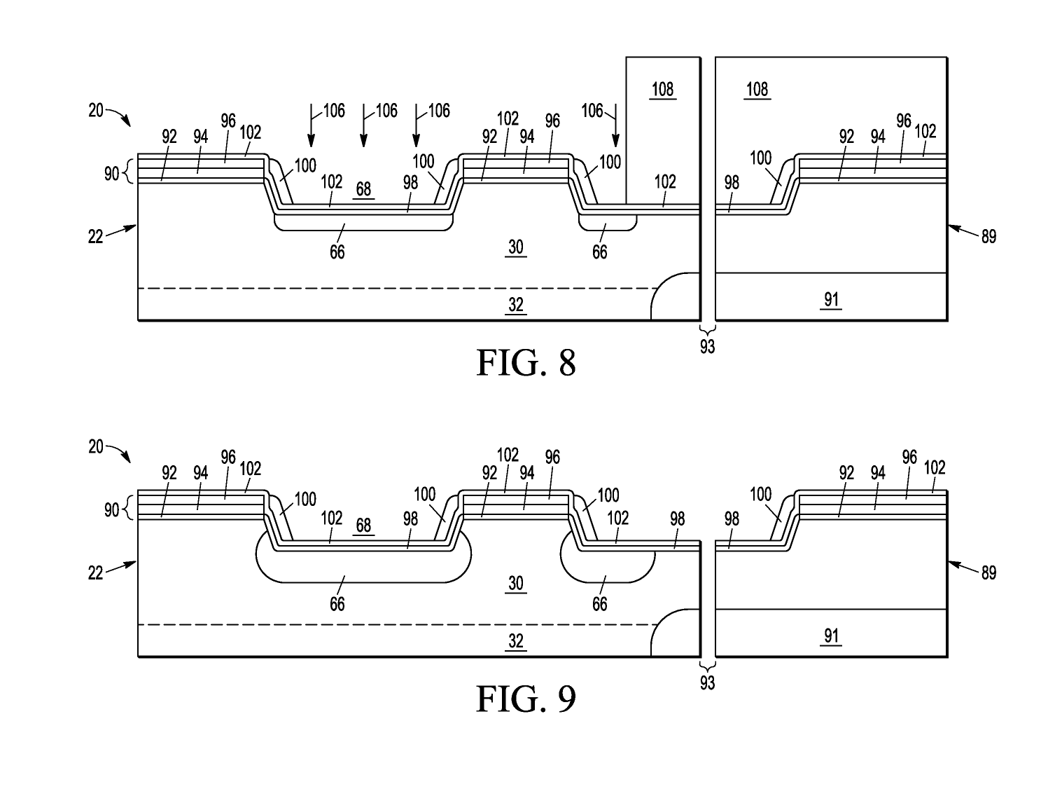

FIG. 8 illustrates partially-completed semiconductor device 20 during the SIBL implant. As indicated in FIG. 8 by arrows 106, impurity dopant ions are implanted into the regions of semiconductor substrate 32 exposed through SIBL stack openings 95 (identified in FIGS. 4-7) to create SIBL regions 66 beneath shallow trenches 68. In one embodiment, the parameters of the

SIBL implant are controlled to produce SIBL regions 66 immediately below trenches 68 such that the upper portions of SIBL regions 66 are contiguous with the bottom surface of trenches 68. The ions may be implanted into semiconductor substrate 32 utilizing an implant that is non-tilted such that trajectory of ion travel is substantially orthogonal to the upper surface of substrate 32. In embodiments wherein it is desired to create N-type SIBL regions 66, phosphorous or arsenic ions can be implanted during the SIBL implant. Conversely, in embodiments wherein P-type SIBL regions 66 are created, boron ions can be implanted. As indicated in FIG. 8, neighboring transistor 89 and any additional, non-HBT components (e.g., one or more CMOS devices) included within semiconductor device 20 may be covered by a mask 108 using, for example, a conventional photoresist material prior to the performance of the SIBL implant.

The acceleration voltage and dosage utilized during the SIBL implant will inevitably vary depending upon device characteristics and the desired electrical and physical characteristics of regions 66. However, in one non-limiting example wherein arsenic ions are implanted into substrate 32 to create N-type buried layers therein, an acceleration voltage of about 100 keV and a dose of about 6.0×10¹⁵ cm⁻² may be utilized. SIBL regions 66 self-align to openings 95 provided through SIBL stack 90 and sidewall spacers 100, which collectively serve as an implant mask during ion implantation. Notably, few, if any, ions penetrate SIBL stack 90 during the SIBL implant due, at least in part, to the inclusion of sacrificial implant block layer 96 within SIBL stack 90; e.g., in a preferred embodiment, sacrificial implant block layer 96 has a thickness sufficient to block at least 99.9% of ion penetration through SIBL stack 70 during implantation of the ions into semiconductor substrate. Stated differently, ions are implanted into semiconductor substrate 32 at a predetermined energy level at which penetration of the ions through patterned SIBL stack 70 is substantially prevented to create SIBL regions 66 within substrate 32 and beneath shallow trenches 68. In this manner, undesired doping of the device active areas during the SIBL implant is avoided or at least minimized, even when polish stop layer 94 is relatively thin (e.g., characterized by a thickness less than about 2000 angstroms and, in certain cases, less than about 1500 angstroms) and/or a relatively high energy implant is performed. The thickness of sacrificial implant block layer 96 can, of course, be tailored to achieve the desired blocking capability depending upon the characteristics of the SIBL ion implantation. After the SIBL implant, semiconductor device 20 may be subjected to a rapid thermal anneal at a predetermined temperature (e.g., about 1080° C.) to diffuse the implanted ions into substrate 32 and enlarge SIBL regions 66. The resultant structure is shown in FIG. 9.

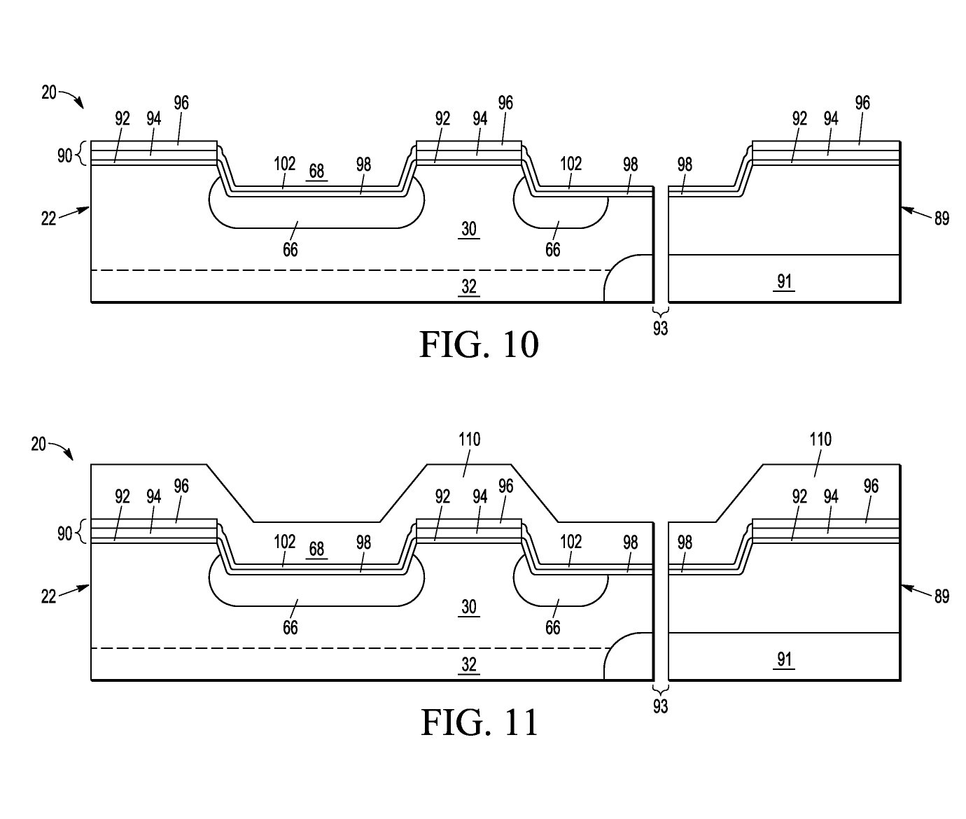

Advancing to FIG. 10, sidewall spacers 100 are next removed utilizing, for example, a wet etch; e.g., a hot phosphoric etch may be performed to remove sidewall spacers 100 when formed from nitride. Semiconductor device 20 may then be cleaned by, for example, exposure to a liquid H₂SO₄/H₂O₂ mixture (commonly referred to as a “piranha etch”). Those portions of oxide layer 102 overlaying sacrificial implant block layer 96 may likewise be removed by etching. A trench fill process is then utilized to fill, at least in part, shallow trenches 68 with a dielectric material. For example, as illustrated in FIG. 11, a dielectric layer 110 may be deposited over semiconductor device 20 and, specifically, over the upper surface of patterned SIBL stack 90 and into shallow trenches 68 such that each trench 68 is filled, in its substantial entirety, by the dielectric material. In one implementation, dielectric layer 110 is an oxide (e.g., a TEOS oxide or a high density plasma oxide) blanket deposited to a thickness of, for example, about 7500 angstroms. Dielectric layer 110 can be formed from the same material or a different material than is sacrificial implant block layer 96; e.g., in one embodiment, dielectric layer 110 and block layer 96 are each composed of an oxide such that layers 110 and 96 collectively form an oxide-on-oxide structure that is readily removable during the below-described CMP process. The CMP polish rates of the materials from which dielectric layer 110 and sacrificial implant block layer 96 are formed preferably differ by no more than 50%, although this need not always be the case. If desired, densification may be performed after deposition of dielectric layer 110 by, for example, rapid thermal anneal.

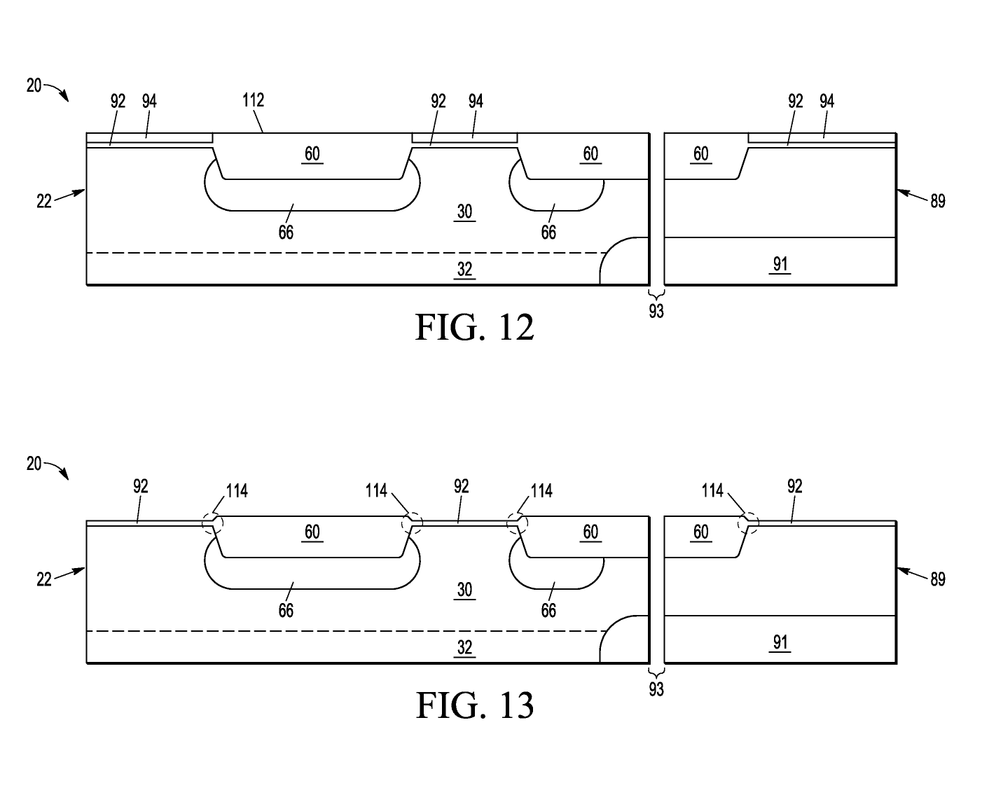

FIG. 12 illustrates semiconductor device 20 after CMP polishing. As can be seen, polishing has removed the overburden from the trench fill process and imparted 20 semiconductor device with a substantially planar upper surface 112 through which the polish stop layer 94 is exposed. CMP polishing also results in the removal of sacrificial implant block layer 96 to complete the formation of the dielectric-filled trenches 60 (also referred to as “shallow trench isolation features”) above SIBL regions 66. In embodiments wherein sacrificial implant block layer 96 is formed from a material having a removal rate similar to that of trench fill layer 110, such as when block layer 96 and layer 110 are each formed from an oxide, polishing can be continued from the uppermost portions of trench fill layer 110, through block layer 96, and to polish stop layer 94 without any significant changing in operational parameters. Thus, in such embodiments, sacrificial implant block layer 96 is effectively transparent to the CMP process; that is, sacrificial implant block layer 96 effectively merges with the material utilized to fill the shallow trenches etched into substrate 32. After the CMP process, polish stop layer 94 may be removed or stripped by etching to yield the structure shown in FIG. 13; e.g., in embodiments wherein polish stop layer 94 is composed of an active nitride, a hot phosphoric etch may be utilized to remove layer 94. As indicated in FIG. 12 by circles 114, small steps may be created proximate the upper edges of filled trenches 60 due to removal of polish stop layer 94; however, in embodiments wherein polish stop layer 94 is formed to be relatively thin (e.g., to have a thickness less than about 2000 angstroms and, preferably, a thickness less than about 1500 angstroms), the step height is minimized. Conventional front end processing steps may then be preformed to complete the production of semiconductor device 20 and yield the finished device shown in FIG. 1.

The foregoing has thus provided exemplary embodiments of a method for fabricating a semiconductor device including Sub-Isolation Buried Layers wherein undesired doping of the device active areas during the SIBL implant is minimized or entirely prevented. While described above in conjunction with a particular type of semiconductor device, namely, a semiconductor device including a heterojunction bipolar transistor, embodiments of the fabrication method can be utilized to fabricate various different types of semiconductor devices including SIBL regions. Further emphasizing this point, FIGS. 14 and 15 are cross-sectional views of a semiconductor device 120 in partially-completed and completed states, respectively, and produced in accordance with a further exemplary embodiment of the semiconductor fabrication method. In this particular example, semiconductor device 120 includes or consists of a voltage-variable capacitor or varactor 122 and, specifically, a PN junction varactor 122. As can be seen in FIG. 15, when completed, varactor 122 includes active areas 124, 126, and 128 formed within well 130 created within semiconductor substrate 132. An anode region 135 (e.g., P-type) is formed within active areas 124 and 128 (e.g., N-type), and a cathode region 137 (e.g., N-type) is formed within active area 126 (e.g., P-type). Shallow trench isolation structures in the form of dielectric-filled trenches 134 are formed between device active areas 124, 126, and 128; and SIBL regions 136 are formed beneath trenches 134. During the fabrication of device 20, and as represented in FIG. 14 by arrows 138, SIBL regions 136 are formed utilizing a SIBL implantation process during which substrate 132 is bombarded with ions. As was previously the case, an SIBL stack 140 is formed over the upper surface of substrate 132 and includes a base layer 146, a polish stop layer 144 overlaying base layer 146, and a sacrificial implant block layer 142 overlaying polish stop layer 144. By way of non-limiting example, base layer 146 may be formed from a pad oxide grown on semiconductor substrate 132, polish stop layer 144 may be formed from a nitride deposited over base layer 146, and sacrificial implant block layer 142 may be formed from an oxide deposited over polish stop layer 144.

Due, at least in part, to the inclusion of sacrificial implant therein, SIBL stack 140 effectively prevents or minimizes the undesired doping of active areas 124, 126, and 128 during the SIBL implant, which could otherwise negatively impact the capacitance of varactor 122. After ion implantation, shallow trenches 148, which were previously-etched into substrate 132 through the openings provide in the patterned SIBL stack 140, are filled with a dielectric material (e.g., a flowable oxide) to yield filled trenches 134 (FIG. 15); and CMP processing may be performed to remove the overburden resulting from the trench fill process along with sacrificial implant block layer 142. Additional processing steps are then performed to complete semiconductor device 120 and yield the structure shown in FIG. 15.

The foregoing has thus provided multiple embodiments of a method for fabricating a semiconductor device. In one embodiment, the method includes providing a semiconductor substrate including a region of a first conductivity type, and forming a Sub-Isolation Buried Layer (SIBL) stack over the semiconductor substrate. The SIBL stack includes: (i) a polish stop layer overlaying the semiconductor substrate, and (ii) a sacrificial implant block overlaying over the polish stop layer. The SIBL stack is patterned to create at least one opening therein, and the semiconductor substrate is etched through the opening of the patterned SIBL stack to produce at least one trench in the semiconductor substrate. Ions of a second conductivity type are implanted into the semiconductor substrate at a predetermined energy level at which penetration of the ions through the patterned SIBL stack is substantially prevented to create a SIBL region within the semiconductor substrate beneath the trench. After implanting ions into the semiconductor substrate, a trench fill material is deposited over the patterned SIBL stack and into the trench. The semiconductor device is then polished to remove a portion of the trench fill material along with the sacrificial implant block layer and impart the semiconductor device with a substantially planar upper surface through which the polish stop layer is exposed.

In another embodiment, the method for fabricating a semiconductor device includes forming a hardmask stack over a semiconductor substrate. The hardmask stack includes an oxide layer, a nitride layer deposited over the oxide layer, and a sacrificial implant block layer deposited over the nitride layer. The hardmask stack is patterned to create a plurality of openings therein. The semiconductor substrate is then etched through the plurality of openings in the patterned hardmask stack to produce a plurality of trenches in the semiconductor substrate. Ions are implanted into the semiconductor substrate to create doped regions in the semiconductor substrate proximate the bottom of at least one of the plurality of trenches and self-aligned to at least one of the openings in the hardmask stack. During the ion implantation process, ions can be implanted into the semiconductor substrate through all openings in the hardmask or SIBL stack such that an SIBL region is formed proximate the bottom of each of the shallow trenches; or, alternatively, a mask may be formed over one or more of the openings in the hardmask stack such that ions are only implanted into a subset of the plurality trenches and, therefore, SIBL regions are only created below certain trenches within the semiconductor substrate, while SIBL regions are not created below the other trenches formed in the substrate. After implanting ions into the semiconductor substrate, a dielectric material is deposited over the patterned hardmask stack and into the trenches. The semiconductor device is then polished to remove a portion of the deposited dielectric material and the sacrificial implant block layer.

In a still further embodiment, the method includes providing a semiconductor substrate and forming a Sub-Isolation Buried Layer (SIBL) stack over the semiconductor substrate. The SIBL stack is patterned to create a plurality of openings therein. The semiconductor substrate is etched through the openings in the patterned SIBL stack to produce a plurality of trenches in the semiconductor substrate separating a plurality of device active areas. An SIBL implant is then performed to create SIBL regions in the semiconductor substrate self-aligned at least one of the openings in the patterned SIBL stack, the SIBL stack substantially inhibiting penetration of the ions into the plurality of device active areas. As noted above, the SIBL implant can be performed such that ions are implanted into each trench formed in the semiconductor substrate to create an SIBL region below each trench; or a mask layer may be formed covering or filling selected openings in the SIBL stack prior to the SIBL implant, and ions may be implanted into and SIBL regions may only be created below a subset of the trenches. In certain cases, the SIBL stack includes a base layer formed over the semiconductor substrate, a polish stop layer formed over the base layer, and a blanket oxide layer formed over the polish stop layer. A CMP process may then be utilized to remove the blanket oxide layer. The method may also include depositing an oxide layer over the semiconductor substrate and into the trenches, and removing portions of the oxide layer along with a blanket oxide layer during the CMP process to impart the semiconductor device with a substantially planar upper surface through which the polish stop layer is exposed.

While at least one exemplary embodiment has been presented in the foregoing Detailed Description, it should be appreciated that a vast number of variations exist. It should also be appreciated that the exemplary embodiment or exemplary embodiments are only examples, and are not intended to limit the scope, applicability, or configuration of the invention in any way. Rather, the foregoing Detailed Description will provide those skilled in the art with a convenient road map for implementing an exemplary embodiment of the invention. It being understood that various changes may be made in the function and arrangement of elements described in an exemplary embodiment without departing from the scope of the invention as set-forth in the appended claims.

What is claimed is:

1. A method for fabricating a semiconductor device, the method comprising:
providing a semiconductor substrate including a region of a first conductivity type;
forming a Sub-Isolation Buried Layer (SIBL) stack over the semiconductor substrate, the SIBL stack comprising:
a polish stop layer overlaying the semiconductor substrate; and
a sacrificial implant block overlaying over the polish stop layer;
patterning the SIBL stack to create at least one opening therein;
etching the semiconductor substrate through the opening of the patterned SIBL stack to produce at least one trench in the semiconductor substrate;
implanting ions of a second conductivity type into the semiconductor substrate at a predetermined energy level at which penetration of the ions through the patterned SIBL stack is substantially prevented to create a SIBL region within the semiconductor substrate beneath the trench;
after implanting ions into the semiconductor substrate, depositing a trench fill material over the patterned SIBL stack and into the trench; and
polishing the semiconductor device to remove a portion of the trench fill material along with the sacrificial implant block layer and impart the semiconductor device with a substantially planar upper surface through which the polish stop layer is exposed.

2. The method of claim 1 wherein polishing the semiconductor device comprises subjecting the partially-completed semiconductor device to a chemical mechanical planarization (CMP) process in the presence of a slurry having a chemistry preferentially removing the trench fill material and the sacrificial implant block layer over the polish stop layer during the CMP process.

3. The method of claim 1 wherein forming a SIBL stack comprises depositing a nitride layer over the semiconductor substrate to produce the polish stop layer.

4. The method of claim 1 wherein the polish stop layer is deposited to a thickness less than about 2000 angstroms.

5. The method of claim 1 wherein the sacrificial implant block layer has a thickness sufficient to block at least 99.9% of ion penetration through the SIBL stack during implantation of the ions into semiconductor substrate at the predetermined energy level.

6. The method of claim 1 wherein, during formation of the SIBL stack, the sacrificial implant block layer is imparted with a thickness between about 200 and about 2000 angstroms.

7. The method of claim 1 wherein, during formation of the SIBL stack, the sacrificial implant block layer is formed by depositing an oxide layer over the polish stop layer.

8. The method of claim 7 wherein forming a SIBL stack further comprises heat treating the sacrificial implant block layer after deposition thereof to densify the sacrificial implant block layer and decrease the rate at which the sacrificial implant block layer is removed during polishing.

9. The method of claim 1 wherein the sacrificial implant block layer comprises an oxide deposited utilizing a tetraethylorthosilicate source.

10. The method of claim 1 wherein formation of the sacrificial implant block layer comprises deposition of a high density plasma oxide.

11. The method of claim 1 wherein the formation of the sacrificial implant block layer comprises depositing polysilicon.

12. The method of claim 1 wherein depositing a trench fill material over the patterned SIBL stack and into the trench comprises blanket depositing a first oxide over the patterned SIBL stack and into the trench.

13. The method of claim 1 wherein forming a SIBL stack over the semiconductor substrate comprises forming the SIBL stack to further include a pad oxide layer between the semiconductor substrate and the polish stop layer.

14. The method of claim 1 further comprising, after polishing the partially-completed semiconductor device, exposing the semiconductor device to an etchant to remove the polish stop layer.

15. The method of claim 1 wherein the semiconductor device is a bipolar transistor.

16. The method of claim 1 wherein the semiconductor device is a varactor.

17. A method for fabricating a semiconductor device, the method comprising:
forming a hardmask stack over a semiconductor substrate including an oxide layer, a nitride layer deposited over the oxide layer, and a sacrificial implant block layer deposited over the nitride layer;
patterning the hardmask stack to create a plurality of openings therein;
etching the semiconductor substrate through the plurality of openings in the patterned hardmask stack to produce a plurality of trenches in the semiconductor substrate;
implanting ions into the semiconductor substrate to create at least one doped region in the semiconductor substrate proximate the bottom of at least one of the plurality of trenches and self-aligned to at least one of the openings in the hardmask stack;
after implanting ions into the semiconductor substrate, depositing a dielectric material over the patterned hardmask stack and into the trenches; and
polishing the semiconductor device to remove a portion of the deposited dielectric material and the sacrificial implant block layer.

18. The method of claim 17 wherein the sacrificial implant block layer comprises one of the group consisting of polysilicon and an oxide.

19. The method of claim 17 wherein the sacrificial implant block layer comprises an oxide, and wherein the method further comprises heat treating the semiconductor device to densify the sacrificial implant block layer after deposition thereof.

20. A method for fabricating a semiconductor device, the method comprising:
providing a semiconductor substrate;
forming a Sub-Isolation Buried Layer (SIBL) stack over the semiconductor substrate;
patterning the SIBL stack to create a plurality of openings therein;
etching the semiconductor substrate through the openings in the patterned SIBL stack to produce a plurality of trenches in the semiconductor substrate separating a plurality of device active areas; and
performing a SIBL implant to create SIBL regions in the semiconductor substrate self-aligned at least one of the openings in the patterned SIBL stack, the SIBL stack substantially inhibiting penetration of the ions into the plurality of device active areas
